(19) United States
(12) Patent Application Publication
(10) Pub. No.: US 2011/0188329 A1
(43) Pub. Date: Aug. 4, 2011

(54) SEMICONDUCTOR INTEGRATED CIRCUIT

(75) Inventors: Takayuki Kawahara, Higashiyamato (JP); Masanao Yamaoka, Kodaira (JP); Nobuyuki Sugii, Tokyo (JP)

(73) Assignee: RENESAS ELECTRONICS CORPORATION

(21) Appl. No.: 13/086,377

(22) Filed: Apr. 13, 2011

Related U.S. Application Data
(63) Continuation of application No. 11/960,680, filed on Dec. 19, 2007.

(30) Foreign Application Priority Data
Feb. 22, 2007 (JP) 2007-041554

(51) Int. Cl. G11C 7/00; H01L 27/088

(52) U.S. Cl. 365/189.16; 257/392; 257/E27.06

(57) ABSTRACT

The semiconductor integrated circuit (1) has a memory (4) and a logic circuit (5), which are mixedly palletized on a silicon substrate (2). The memory includes a partially-depleted type nMOS (6) having an SOI structure and formed on UTB (3). The partially-depleted type nMOS has a backgate region (14) under UTB, to which a voltage can be applied independently of a corresponding gate terminal. The logic circuit includes an nMOS (7) and a pMOS (8), and both are of a fully-depleted type, formed on UTB and have an SOI structure. The fully-depleted type nMOS and pMOS have backgate regions (14, 22) under respective UTBs, to which voltages can be applied independently of the corresponding gate terminals

### CLAIM OF PRIORITY

The Present application claims priority from Japanese application JP 2007-041554 filed on Feb. 22, 2007, the content of which is hereby incorporated by reference into this application.

### FIELD OF THE INVENTION

The present invention relates to a semiconductor integrated circuit, and particularly to a technique useful in application to a low-power processor with a high-density integrated memory.

### BACKGROUND OF THE INVENTION

MOS (Metal-Oxide-Semiconductor) transistors having an SOI (Silicon On Insulator) structure are classified into a fully-depleted type transistor and a partially-depleted type transistor; the fully-depleted type transistor has a silicon layer of a small thickness on an insulating film, and the silicon layer of the partially-depleted type transistor has a larger thickness. Patent Document 1, JP-A-9-135030, discloses a semiconductor integrated circuit device including fully-depleted type and partially-depleted type transistors which have a SOI structure and are mixedly palletized on a semiconductor substrate. On the other hand, Patent Document 2, JP-A-2003-68877 discloses a memory using a partially-depleted type transistor, which can store binary information by a state where carriers produced by impact-ionization caused by an operation of the MOS transistor have been poured into an undepleted region and a state where the carriers have been brought out by applying a forward bias to a PN junction on the side of a drain of the MOS transistor.

### SUMMARY OF THE INVENTION

The inventor examined means including forming a logic circuit with a fully-depleted type transistor, forming a memory with a partially-depleted type transistor, and mixedly palletizing the logic circuit and memory on one semiconductor substrate. Patent Document 1 just contains the description that a circuit which needs to be resistant to a high voltage is configured with a partially-depleted type transistor and a circuit which requires a low power and a high speed is configured with a fully-depleted type transistor. Further, Patent Document 2 presents only the description on the arrangement that a partially-depleted type transistor is used in a memory cell and two states different in threshold voltage are developed. The inventor discovered that it is insufficient only to apply the inventions disclosed in Patent Documents 1 and 2 when a logic circuit and a memory are mixedly palletized on one semiconductor substrate, and the following are required. The first is to make controllable the speed and power consumption according to the operation mode. The second is to improve the retention characteristic.

Therefore, it is an object of the invention to provide a semiconductor integrated circuit, which allows the speed and power consumption to be controlled according to the operation mode, and enables the improvement of the retention characteristic.

The above and other objects and novel features of the invention will become apparent from the description hereof and the accompanying drawings.

Of the semiconductor integrated circuits disclosed herein, the representative one will be described below in brief.

The partially-depleted type first MOS transistor having the SOI structure has a first semiconductor region under an insulating film, which is arranged so that a voltage can be applied thereto independently of its gate terminal, and is used to form a storage device. The fully-depleted type second MOS transistor having the SOI structure has a second semiconductor region under an insulating film, which is arranged so that a voltage can be applied thereto independently of its gate terminal, and is used to form a logic circuit. As a result, when voltages applied to the first and second semiconductor regions are controlled according to the operation mode, the speed and power consumption can be controlled according to the operation mode, and therefore the retention characteristic can be improved.

### BRIEF DESCRIPTION OF THE DRAWINGS

FIG. 1 is a drawing exemplifying a cross sectional structure of a semiconductor integrated circuit according to the first embodiment of the invention;

FIG. 2 is an illustration exemplifying a circuit configuration of the semiconductor integrated circuit shown in FIG. 1;

FIG. 3 is an illustration exemplifying a layout of a memory cell array;

FIG. 4 is a drawing showing a cross section of the memory cell array taken along the line A-A′;

FIG. 5 is a drawing showing a cross section of the memory cell array taken along the line B-B′;

FIG. 6 is a drawing exemplifying terminals of an nMOS making a memory cell;

FIG. 7 is an illustration exemplifying values of voltages applied to the terminals of the memory cell according to the operation mode;

FIG. 8 is an illustration exemplifying a configuration of a chip with a CPU and a memory thereon;

FIG. 9 is an illustration exemplifying a circuit configuration of a bank B11;

FIG. 10 is an illustration exemplifying the cross sectional structure of a semiconductor integrated circuit according to the second embodiment of the invention;

FIG. 11 is an illustration exemplifying the circuit configuration including an input-protection device with an nMOS and a pMOS, which have bulk structures;

FIG. 12 is an illustration exemplifying the circuit configuration of the semiconductor integrated circuit shown in FIG. 10;

FIG. 13 is an illustration exemplifying the cross sectional structure of a semiconductor integrated circuit according to the third embodiment of the invention;

FIG. 14 is an illustration showing an example of the structure of the semiconductor integrated circuit shown in FIG. 13 up to its upper-layer conductor line;

FIG. 15 is an illustration showing an example of the situation where the semiconductor integrated circuits are stacked;

FIG. 16 is an illustration showing an example of the situation where communication devices are placed on the stacked semiconductor integrated circuits;

FIG. 17 is an illustration showing an example where coils are used as the communication devices; and

FIG. 18 is an illustration showing an example where a light-emitting device and light-receiving device are used as the communication devices.

### DETAILED DESCRIPTION OF THE PREFERRED EMBODIMENTS

### 1. Summary of the Preferred Embodiments

The outlines of representative embodiments of the invention disclosed herein will be described first. Each of reference characters in the drawings in parentheses, by which reference is made in the outline descriptions concerning the representative embodiments, is just for exemplifying what is included in the concept of a constituent accompanied with the character.

[1] A semiconductor integrated circuit associated with a representative embodiment of the invention includes a first MOS transistor (6) of a partially-depleted type, and second MOS transistors (7, 8) of a fully-depleted type, which are separated electrically and formed on respective insulating films (3) and have the SOI structure. The first MOS transistor has a first semiconductor region (14) under the insulating film, to which a voltage can be applied independently of a gate terminal thereof. The second MOS transistors have second semiconductor regions (14A, 22) under the insulating films, to which voltages can be applied independently of gate terminals thereof. The first MOS transistor forms a storage device (4) which holds information by a first state that an excessive amount of carriers is accumulated in a third semiconductor region (12) for forming a channel and a second state that the excessive amount of carriers is discharged from the third semiconductor region. The second transistors form a logic circuit (5).

According to the arrangement as described above, in the first MOS transistor, a voltage applied to the first semiconductor region opposed to the third semiconductor region for forming a channel with the insulating film interposed therebetween is made controllable. Therefore, when the voltage is controlled according to the operation mode, the property of retaining carriers stored in the undepleted region is controlled. Thus, the retention characteristic can be improved. In the second MOS transistors, voltages applied to the second semiconductor regions opposed to the semiconductor regions for forming a channel with the insulating films interposed therebetween are made controllable. Therefore, the voltages can be controlled according to the operation mode. Thus, the speed can be increased when the threshold voltage is lowered, and the power consumption can be suppressed when the threshold voltage is increased. As a result, the speed and power consumption can be controlled according to the operation mode in the second MOS transistors.

As one specific form, the semiconductor integrated circuit further includes a fourth semiconductor region (16) and a fifth semiconductor region (18). The fourth semiconductor region is disposed between the first semiconductor region and a semiconductor substrate (2) when the first semiconductor region is coincident in conductivity type with the semiconductor substrate, and has a conductivity type differing from the conductivity type of the semiconductor substrate. The fifth semiconductor region is coincident in conductivity type with the fourth semiconductor region, and is a semiconductor region used for applying a voltage to the fourth semiconductor region. According to the arrangement as described above, the fourth semiconductor region is disposed between the first semiconductor region and semiconductor substrate, and a reverse bias is applied between the first and fourth semiconductor regions by applying a voltage to the fourth semiconductor region through the fifth semiconductor region. As a result, the first semiconductor region can be separated from the semiconductor substrate electrically, whereby the leakage current can be prevented from being produced.

As another form, the semiconductor integrated circuit further includes a sixth semiconductor region (16A) and a seventh semiconductor region (18A). The sixth semiconductor region is disposed between the second semiconductor region and semiconductor substrate when the second semiconductor region is coincident in conductivity type with the semiconductor substrate, and has a conductivity type differing from the conductivity type of the semiconductor substrate. The seventh semiconductor region is coincident in conductivity type with the sixth semiconductor region, and is a semiconductor region used for applying a voltage to the sixth semiconductor region. According to the arrangement as described above, the sixth semiconductor region is disposed between the second semiconductor region and semiconductor substrate, and a reverse bias is applied between the second and sixth semiconductor regions by applying a voltage to the sixth semiconductor region through the seventh semiconductor region. As a result, the second semiconductor region can be separated from the semiconductor substrate electrically, whereby the leakage current can be prevented from being produced.

As still another form, the semiconductor integrated circuit further includes third MOS transistors (51, 52) having a bulk structure. The third MOS transistors each have an eighth semiconductor region for forming a channel. The eighth semiconductor regions have ninth semiconductor regions (14B, 22B) to which voltages can be applied independently of gate terminals of the third MOS transistors. According to the arrangement as described above, in the third MOS transistors, the threshold voltages can be controlled by using the ninth semiconductor regions to apply a voltage. Further, it is possible to make good use of design assets of an analog circuit including third MOS transistors having the bulk structure, etc.

As still another form, the third MOS transistors form an input-protection device (50) connected to an external input terminal (53) . The input-protection device has an nMOS with a gate connected to a ground terminal and a pMOS with a gate connected to a power-supply terminal. According to the arrangement as described above, when a positive or negative high-voltage surge is applied to the input terminal, a forward bias is applied between the source of each third MOS transistor and the semiconductor substrate, and thus the high voltage can be released through the semiconductor substrate.

As still another form, the semiconductor integrated circuit further includes a tenth semiconductor region (16B) and an eleventh semiconductor region (18B) . The tenth semiconductor region is disposed between the eighth semiconductor region and semiconductor substrate when the eighth semiconductor region is coincident in conductivity type with the semiconductor substrate, and has a conductivity type differing from the conductivity type of the semiconductor substrate. The eleventh semiconductor region is coincident in conductivity type with the tenth semiconductor region, and is a semiconductor region used for applying a voltage to the tenth semiconductor region. According to the arrangement as described above, the tenth semiconductor region is disposed between the eighth semiconductor region and semiconductor substrate, and a reverse bias is applied between the eighth and tenth semiconductor regions by applying a voltage to the tenth semiconductor region through the eleventh semiconductor region. As a result, the eighth semiconductor region can be separated from the semiconductor substrate electrically, whereby the leakage current can be prevented from being produced.

[2] A semiconductor integrated circuit associated with a representative embodiment of the invention includes a first MOS transistor (6) of a partially-depleted type, and second MOS transistors (7, 8) of a fully-depleted type, which are separated electrically and formed on respective first insulating films (3) and have the SOI structure. The first MOS transistor has a first semiconductor region (61) under the first insulating film, to which a voltage can be applied independently of a gate terminal thereof. The second MOS transistors have second semiconductor regions (62, 63) under the first insulating films, to which voltages can be applied independently of gate terminals thereof. The semiconductor integrated circuit has a second insulating film (60) disposed between the first and second semiconductor regions and semiconductor substrate (2). The first MOS transistor forms a storage device (4) which holds information by a first state that an excessive amount of carriers is accumulated in a third semiconductor region (12) for forming a channel and a second state that the excessive amount of carriers is discharged from the third semiconductor region. The second MOS transistors form a logic circuit (5).

The semiconductor integrated circuit is different from the semiconductor integrated circuit stated in [1] in that the first and second semiconductor regions are electrically separated from the semiconductor substrate by the second insulating film interposed therebetween, the structure is further simplified, and the occurrence of leakage current is prevented. Further, as in the case of semiconductor integrated circuit stated in [1], with the first MOS transistor, the retention characteristic can be improved according to the operation mode. Still further, in regard to the second MOS transistors, the speed and power consumption can be controlled according to the operation mode.

[3] A semiconductor integrated circuit associated with a representative embodiment of the invention has a first semiconductor integrated circuit (61A) and a second semiconductor integrated circuit (61B), which are each prepared by removing the semiconductor substrate from under the second insulating film of the above-described semiconductor integrated circuit, wherein one of the first and second semiconductor integrated circuits is stacked on the other. According to the arrangement as described above, the first and second semiconductor integrated circuits each having the second insulating film as an undermost layer can be formed when their semiconductor substrates are removed by a mechanical or chemical process. The first and second semiconductor integrated circuits form layers thinner than the semiconductor integrated circuit as described above. Therefore, even when one of the first and second integrated circuits is stacked on the other, the thickness of the resultant stack is smaller. Thus, a semiconductor integrated circuit highly integrated in the three dimensions can be attained.

As one specific form, the semiconductor integrated circuit further includes a first winding (63A) using a conductor line on the first semiconductor integrated circuit, and a second winding (63B) using a conductor line on the second semiconductor integrated circuit, wherein the first and second semiconductor integrated circuits are coupled with each other by the first and second windings electromagnetically. According to the arrangement as described above, the first and second semiconductor integrated circuits each forma thin layer, and therefore the distance between the first and second windings is made smaller. Thus, the first and second windings can increase the mutual inductance. The current flowing through one of the windings generates a magnetic field, which induces current flowing through the other winding. Hence, a signal arising in the one winding can be read out in the other winding with ease. Therefore, it becomes possible to conduct wireless communication between the first and second semiconductor integrated circuits.

As still another form, the semiconductor integrated circuit further includes a first electrode provided on the first semiconductor integrated circuit, and a second electrode provided on the second semiconductor integrated circuit and opposed to the first electrode, wherein the first and second semiconductor integrated circuits are capacitively coupled by the first and second electrodes. According to the arrangement as described above, the first and second semiconductor integrated circuits each forma thin layer, and therefore the distance between the first and second electrodes can be made extremely small. Hence, the function of a capacitor formed by the first and second electrodes, namely capacitance, can be enhanced. As a result, the wireless communication by capacitance coupling between the first and second semiconductor integrated circuits is facilitated.

As still another form, the semiconductor integrated circuit has a light-emitting device (65A) provided on the first semiconductor integrated circuit, and a light-receiving device (64B) provided on the second semiconductor integrated circuit, wherein the first and second semiconductor integrated circuits use the light-emitting device and light-receiving device to perform optical communication. According to the arrangement as described above, the first and second semiconductor integrated circuits each form a thin layer, and therefore the distance between the light-emitting device and light-receiving device can be made smaller. Hence, even if these devices have a low light emission efficiency or a low light receiving efficiency, it becomes possible to perform optical communication between the first and second semiconductor integrated circuits.

### 2. Further Detailed Description of the Preferred Embodiments

Second, the embodiments will be described further in detail. Best modes of carrying out the invention will be described in detail below with reference to the drawings. In all the drawings for explaining the best modes of carrying out the invention, like members having the same functions are identified by the same reference characters, and the iteration of the description thereof is omitted.

Now, the details of the embodiments will be described.

### First Embodiment

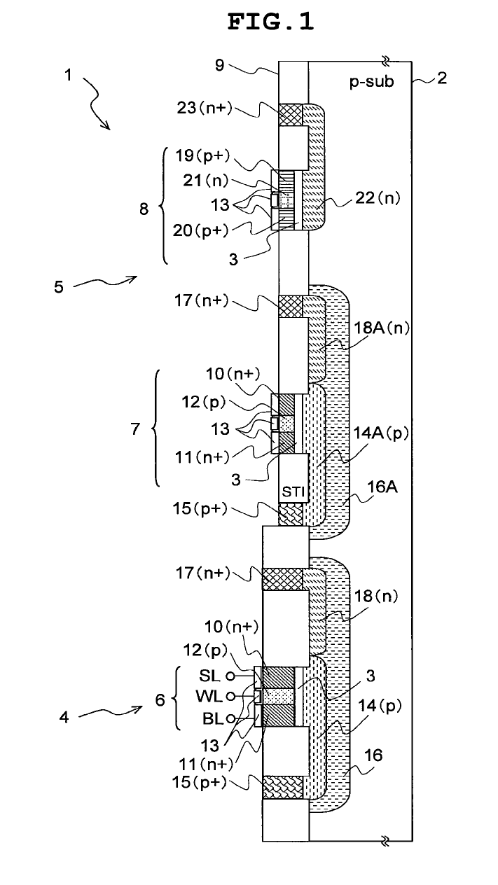

Referring to FIG. 1, the cross sectional structure of a semiconductor integrated circuit according to the first embodiment of the invention is exemplified. The SOI structure is adopted for the semiconductor integrated circuit 1; the integrated circuit has a p-type silicon substrate (p-sub) 2 as an underlying layer, and an n-type MOS transistor (hereinafter referred to as nMOS), a p-type MOS transistor (hereinafter referred to as pMOS), etc., which are formed on an insulating film of e.g. not more than 30 nanometers—a buried oxide (BOX) film layer (hereinafter referred to as UTB) 3. The semiconductor integrated circuit 1 has a memory (Memory) 4 and a logic circuit (LOGIC) 5 mixedly formed on the silicon substrate 2. Memory 4 has a plurality of memory cells. Each memory cell is formed by an nMOS 6 of a partially-depleted (PD) type. Herein as an example, the memory cell is formed by an nMOS, however it may be a pMOS. The logic circuit 5 has an nMOS 7 and a pMOS 8, which are of a fully-depleted (FD) type. The partially-depleted type nMOS 6 is formed to have a silicon layer on UTB 3, which has a thickness larger than those of the fully-depleted type nMOS 7 and pMOS 8 as shown in the drawing. Also, the nMOS 6, nMOS 7 and pMOS 8 are electrically separated by STI (Shallow Trench Isolation) layer 9 which is a trench type isolation region.

First, the partially-depleted type nMOS 6 will be described. As to the partially-depleted type nMOS 6, an n⁺ region 10 making an n-type source region, and an n⁺ region 11 making an n-type drain region are formed in a silicon layer formed on UTB 3, and further a p-type channel region 12 for forming a channel is formed therebetween. The channel region 12 is connected through a gate-insulating film (not shown) to a gate terminal connected to a word line WL. The n⁺ region 11 is connected to a drain terminal connected to a bit line BL. The n⁺ region 10 is connected to a source terminal connected to a source line SL. The source line connects between memory cells with a diffusion layer, and is connected with a metal line of a low resistance or the like in blocks; each block is composed of a number of memory cells. The gate, drain and source terminals each have a salicide (SC) structure 13 using silicide, which is a compound of silicon and a metal of a high melting point.

In the partially-depleted type nMOS 6, a p-type semiconductor region (hereinafter referred to as backgate region) 14 making a backgate is formed underneath UTB 3. A voltage is applied to the backgate region 14 through a p⁺ region 15 exposed from a surface of the STI layer 9 independently of a gate electrode. At this time, as UTB 3 is as thin as not more than 30 nanometers as described above, even if the voltage to be applied (i.e. substrate-biasing voltage) is low one, an electric field can be produced in the channel region 12, thereby to make possible to control the threshold voltage. The partially-depleted type nMOS 6 forming a memory cell has: a first state that an excessive amount of carriers (holes) produced by impact-ionization resulting from the MOS operation have been poured into an undepleted portion of the channel region 12; and a second state that the excessive holes have been released into the drain by passing a forward electric current between the drain and channel region 12. Therefore, in the partially-depleted type nMOS 6, for example, when the first state is set as data “1” and the second state is set as data “0”, it becomes possible to hold binary information.

In addition, as for the partially-depleted type nMOS 6, as a substrate-biasing voltage to be applied to the backgate region 14 can be controlled depending on an operation mode to be described later (see FIG. 7), e.g. the property of retaining carriers in the first state is made controllable, and therefore the retention characteristic can be improved. Specifically, controlling a substrate-biasing voltage to be applied to the backgate region 14 can produce, in the channel region 12, an electric field which keeps carriers involved with the first state in the undepleted portion. Also, when applying the substrate-biasing voltage thereby to control the threshold voltage, the memory cells can be rewritten at a high speed. Herein, the control of the threshold voltage is performed not only for the improvement of the retention characteristic and speed-up of the rewrite, but also for the reduction in variations of the threshold voltage for each memory cell composed of one nMOS 6 e.g. after fabrication of Memory 4.

Between the backgate region 14 and the silicon substrate 2 is disposed an n-type semiconductor region (hereinafter referred to as dn region) 16. Also, between the dn region 16 and the STI layer 9 is disposed an n region 18 for applying a voltage to the dn region 16 through the n+ region 17 exposed from the surface of the STI layer 9 as shown in the drawing. Applying a voltage to the dn region 16 through the n region 18 is equivalent to reversely biasing between the backgate region 14 and the dn region 16. As a result, the backgate region 14 is electrically separated from the silicon substrate 2, and therefore the occurrence of the leakage of electric current can be presented.

Next, the nMOS 7 of the fully-depleted type will be described. Here, parts having the same functions as those of parts of the partially-depleted type nMOS 6 as described above are identified by the same reference characters, and their descriptions are omitted. The structure of the fully-depleted type nMOS 7 is substantially identical to that of the partially-depleted type nMOS 6 except for the following two points. The first is that the thickness of the silicon layer formed on UTB 3 is thinner. The second is that according to the silicon layer, the thickness of the STI layer 9 is made thinner. Between the backgate region 14A and the silicon substrate 2, a dn region 16A having the same function as the above-described dn region 16 has is disposed. Further, between the dn region 16A and the STI layer 9, an n region 18A having the same function as the above-described n region 18 has is disposed. On this account, also with the fully-depleted type n MOS 7, the threshold voltage can be controlled when the backgate region 14A is used to produce an electric field in the channel region 12.

Now, the fully-depleted type pMOS 8 will be described. In regard to the fully-depleted type pMOS 8, a p⁺ region 19 making a p-type source region and a p⁺ region 20 making a p-type drain region are formed in a silicon layer formed on UTB 3, and further an n-type channel region 21 for forming a channel is formed therebetween. The channel region 21 is connected to a gate terminal through a gate-insulating film (not shown). The p⁺ region 20 is connected to a drain terminal. The p⁺ region 19 is connected to a source terminal. The gate, drain and source terminals each have a salicide structure 13. In the fully-depleted type pMOS 8, an n-type backgate region 22 making a backgate is formed underneath UTB 3. A voltage is applied to the backgate region 22 through a n⁺ region 23 exposed from the surface of the STI layer 9 independently of a gate electrode. At this time, as UTB 3 is as thin as not more than 30 nanometers as described above, even if the substrate-biasing voltage to be applied is low one, an electric field can be produced in the channel region 21, thereby to make possible to control the threshold voltage.

The fully-depleted type nMOS 7 and pMOS 8 as described above form the logic circuit 5, which have UTBs 3 arranged between the backgate regions 14A and 22 and the channel regions 12 and 22 respectively. Therefore, the junction capacities between the drain regions 11 and 20 and the corresponding backgate regions 14A and 22 can be reduced greatly. Because of the control of threshold voltages using the backgate regions 14A and 22, increasing the threshold voltage can reduce the power consumption, and lowering the threshold voltage enables the speed-up. In other words, as for the fully-depleted type nMOS 7 and pMOS 8, when the substrate-biasing voltages applied to the backgate regions 14A and 22 are controlled, the logic circuit 5 whose speed and power consumption are controllable can be formed. Therefore, the semiconductor integrated circuit 1 not only allows Memory 4 and the logic circuit 5 to be mixedly formed on one silicon substrate 2, but also enables the improvement of the retention characteristic of Memory 4 formed by a partially-depleted type transistor, in which the speed and power consumption of the logic circuit 5 formed by fully-depleted type transistors can be made controllable. Further, with the semiconductor integrated circuit 1, as one memory cell is formed by one partially-depleted type transistor, more memory cells can be laid out within Memory 4 and therefore the capacity can be increased.

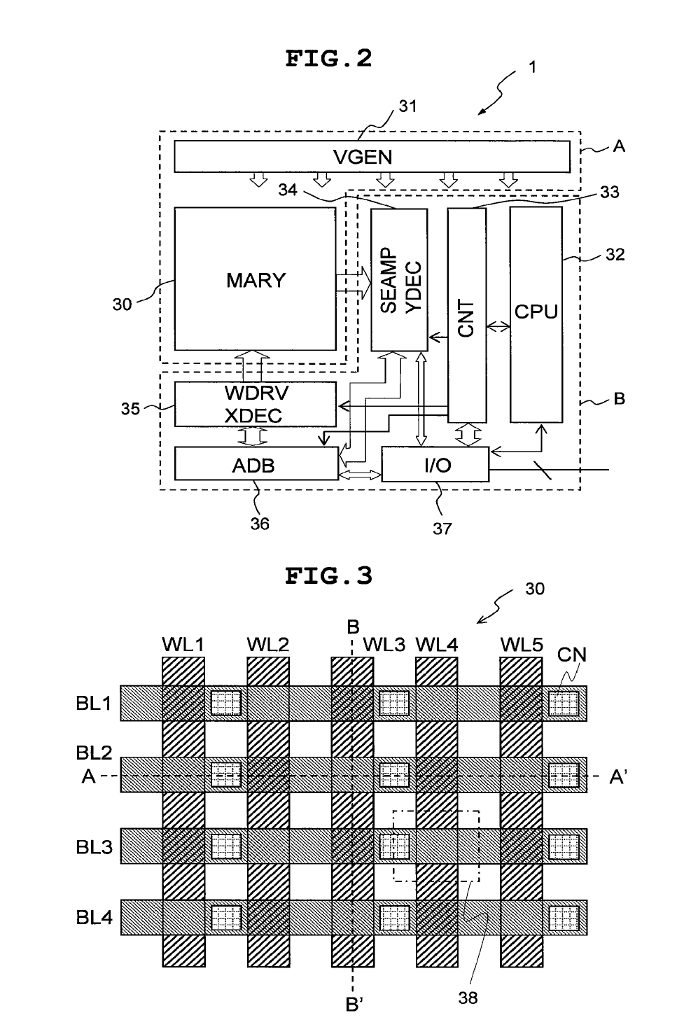

Referring to FIG. 2, a circuit configuration of the semiconductor integrated circuit 1 is exemplified. Here is shown an example of the circuit configuration of the semiconductor integrated circuit 1 applied to a memory circuit. The semiconductor integrated circuit 1 is partitioned off into a region A and a region B on the silicon substrate 2 as described above. The region A includes a memory cell array (MARY) 30 and a power-supply circuit (VGEN) 31, each of which is formed by a MOS of a partially-depleted type. This configuration can improve the retention characteristic of a memory cell of the memory cell array 30. The power-supply circuit 31 can generate a predetermined voltage that is required because a partially-depleted type MOS having a relatively good resistance to a high voltage is used. Further, use of a MOS of a partially-depleted type the same as the type of the memory cells allows the properties to be adjusted easily, and therefore designing of a semiconductor integrated circuit can be facilitated.

The region B includes a CPU 32, a control circuit (CNT) 33, a composite module 34 of a sense amplifier (SEAMP) and a Y decoder (YDEC) , a composite module 35 of a word driver (WDRV) and an X decoder (XDEC), an address buffer (ADB) 36 and an input-output circuit (I/O) 37, and those circuits are constituted by fully-depleted type MOSs. Thus, the circuits in the region B can be controlled in speed and power consumption when the threshold voltages are controlled by the backgates.

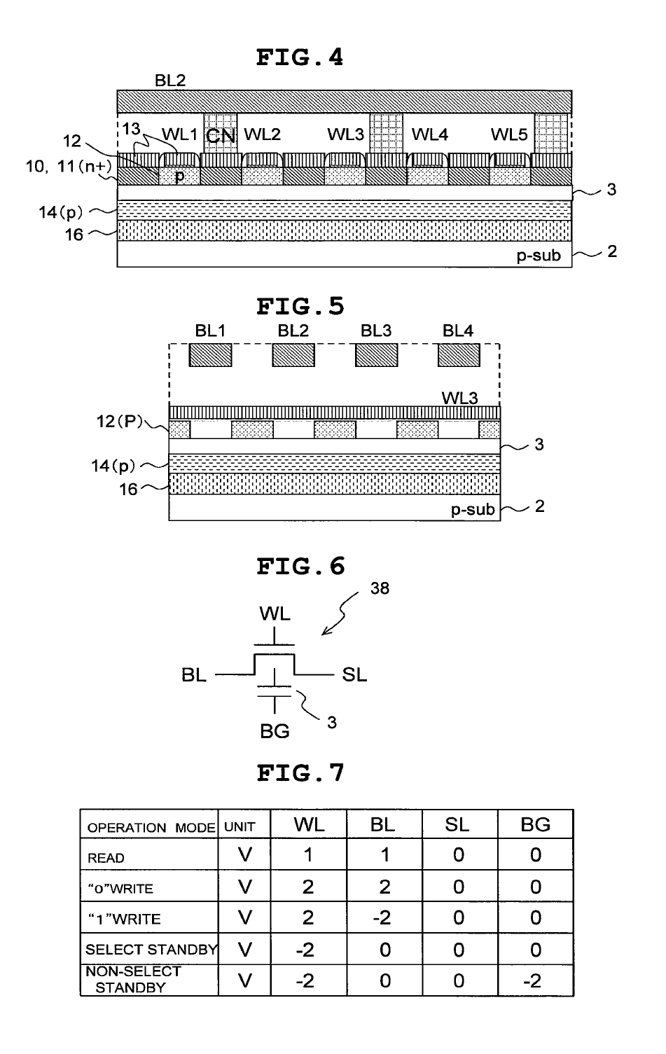

Referring to FIG. 3, a layout of the memory cell array 30 is exemplified. FIG. 4 is a sectional view of the memory cell array 30 taken along the line A-A′. FIG. 5 is a sectional view taken along the line B-B′. The memory cell array 30 is formed by partially-depleted type MOSs. In FIG. 3, a region surrounded by the single dot & dash line represents a unit memory cell 38 configured of one nMOS. As shown in FIG. 3, the memory cell 38 occupies one pitch in a direction of an array of word lines WL1 to WL5 (corresponding to the sum of the line width and interval of the word lines) and one pitch in a direction of an array of bit lines BL1 to BL4 (corresponding to the sum of the line width and interval of the bit lines). In addition, a region CN is used as a region for connecting the drain of the nMOS of the corresponding memory cell with the bit line. Following the established procedure, in which the line width is assumed to be equal to the interval and they are denoted by “F” in general, the memory cell 38 shown in the drawing is formed to have the size of “2 F×2 F”. The cross sectional structure of the memory cell array 30 is as shown in FIGS. 4 and 5. The memory cell array has a structure that nMOSs 6 as shown associated with the memory 4 are arranged in an array, in which a do region 16, a backgate region 14 and UTB 3 are stacked on a silicon substrate 2 used as an undermost layer in this order, and further a partially-depleted type nMOS 6 is formed on UTB 3. Each nMOS 6 can be controlled in threshold voltage and transistor properties when a substrate-biasing voltage is applied to its backgate region 14, as described above.

FIG. 6 is a drawing exemplifying terminals of the nMOS making a memory cell. In the drawing, the reference character BG denotes a backgate terminal for applying a voltage to the backgate region 14. Here is shown one memory cell 38, and further a word line WL, bit line BL and source line SL, which are connected to the terminals, and a backgate terminal BG are exemplified. In FIG. 7, voltages values applied to the terminals of the memory cell according to the operation mode are exemplified. A voltage applied to each terminal is fed in the form of a pulse changing in time during an actual operation. It can be understood by those skilled in the art that the voltages exemplified in FIG. 7 imply the relation of voltages at the time of determining the state of an actual operation.

Now, the relation of voltages will be described below. The table exemplified in FIG. 7 shows five operation modes composed of Read, “0” Write, “1” Write, Select Standby and Non-select Standby, the unit (V: volt), the terminals WL, BL, SL and BG as described above, and voltage values to be applied to the terminals according to the operation modes. In “Read”, a voltage of 1 volt is applied to the word line WL and bit line BL respectively, and the source line SL and backgate terminal BG are made 0 volt. As a result, the states of “0” Write and “1” Write are differentiated by the difference of electric current.

In “0” Write, a voltage of 2 volts are applied to the word line WL and bit line BL respectively, and the source line SL and backgate terminal BG are made 0 volt. As a result, an ON current passes through the transistor, and carriers (i.e. holes) produced by impact-ionization resulting from the MOS operation are poured into an undepleted portion of the channel region 12, whereby a state of a low threshold voltage (e.g. 0.5 volts) is materialized. In “1” Write“, a voltage of 2 volts is applied to the word line WL and −2 volts is applied to the bit line BL, and the source line SL and backgate terminal BG are made 0 volt. As a result, in the drain region of the nMOS connected with the bit line BL, a forward bias is applied to the PN junction, and carriers accumulated in the undepleted portion of the channel region 12 are released therefrom, whereby a state of a high threshold voltage (e.g. 1.5 volts) is materialized.

“Select Standby” refers to a state of a memory cell which is not accessed, provided that the memory cell is one of memory cells of a selected bank, and the memory cell array 30 is controlled in banks. In Select Standby, a voltage of −2 volts is applied to the word line WL, and the bit line BL, source line SL and backgate terminal BG are made 0 volt. “Non-select Standby” refers to a state that no bank per se is selected. Unlike Select Standby, in Non-select Standby a voltage of −2 volts is applied to the backgate terminal BG. In this case, an electric field can be generated in a direction which allows carriers to be kept in the undepleted portion of the channel region 12, and therefore the retention characteristic of the memory cell 38 can be improved.

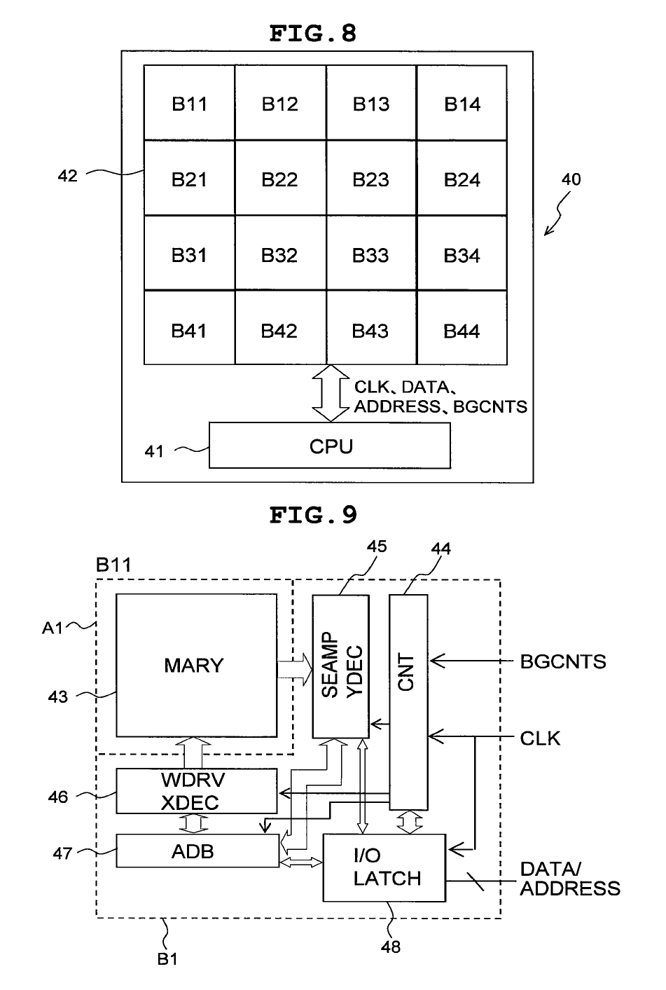

Referring to FIG. 8, the configuration of a chip with a CPU and a memory is exemplified. The chip 40 has a CPU 41 and a memory 42. The CPU 41 includes a MOS of a fully-depleted type. The memory 42 has banks B11 to B44 arranged in the form of a pattern of tiles. The CPU 41 sends and receives a clock CLK, data DATA, an address ADDRESS, and a backgate control signal BGCNTS to and from the banks B11 to B44. FIG. 9 exemplifies the circuit configuration of the bank B11. The other banks B12 to B44 are substantially identical with the bank B11, and their descriptions are omitted here. The bank B11 is partitioned off into a region A1 and a region B1. In the region A1, a memory array (MARY) 43 is disposed, which is formed by partially-depleted type MOSs. In the region B1 are disposed a control circuit (CNT) 44, a composite module 45 of a Y decoder (YDEC) and a sense amplifier (SEAMP), a composite module 46 of an X decoder (XDEC) and a word driver, an address buffer (ADB) 47, and an input-output circuit (I/O) 48 including a latch circuit (LATCH), which are formed by fully-depleted type MOSs. The control circuit 44 accepts, as inputs, the backgate control signal BGCNTS and the clock CLK as shown in the drawing. To the input-output circuit 48, the data DATA and address ADDRESS are input in synchronization with the clock CLK.

Specifically, the bank B11 serves as a memory circuit working in synchronization with the clock CLK, which is read and written based on the address ADDRESS and data DATA input thereto in synchronization with the clock CLK, and outputs data DATA in synchronization with the clock CLK. Also, to the bank B11, the backgate control signal BGCNTS is input from the CPU 41. Now, the control by the CPU 41 when entering the backgate control signal BGCNTS into the memory 42 constituted by the banks Bll to B44 will be described in brief below, in which the memory 42 is mounted on the chip 40 as exemplified in FIG. 8. An upper-layer conductor line (not shown) connects between the CPU 41 and bank B11. The time representing several clocks (e.g. five clocks) is taken from the time when the CPU 41 outputs the data DATA and address ADDRESS to the bank B11 to the time when the bank B11 outputs the data DATA to the CPU 41. Likewise, the other banks B12 to B44 are connected to the CPU 41 by upper-layer conductor lines (not shown) , and require several clocks for the exchange of the data DATA.

Here, attention is paid to the bank B11 and bank B12 next to the bank B11. When the CPU 41 selects the bank B12 and outputs data DATA to the bank B12 for each clock CLK, two or more clocks are needed until data DATA from the bank B12 is delivered to the CPU 41 actually. In other words, until communication between the bank B12 and CPU 41 is completed, the CPU 41 cannot access the bank B12 additionally. However, even for such time, the CPU 41 can accept an order to transfer the bank B11 in the operation mode e.g. from Non-select Standby to Select Standby after completion of the communication with the bank B12 . (See FIG. 7, for the operation mode.) In that case, the CPU 41 then outputs a backgate control signal BGCNTS which reflects that order to the bank B11 before the communication between the bank B12 and CPU 41 is completed. In such arrangement, at the time when the CPU 41 selects the bank B11 actually after the completion of the communication, the backgate control signal BGCNTS has been already output to the bank B11. Therefore, the transfer of the operation mode of the bank B11 can be carried out without any trouble.

### Second Embodiment

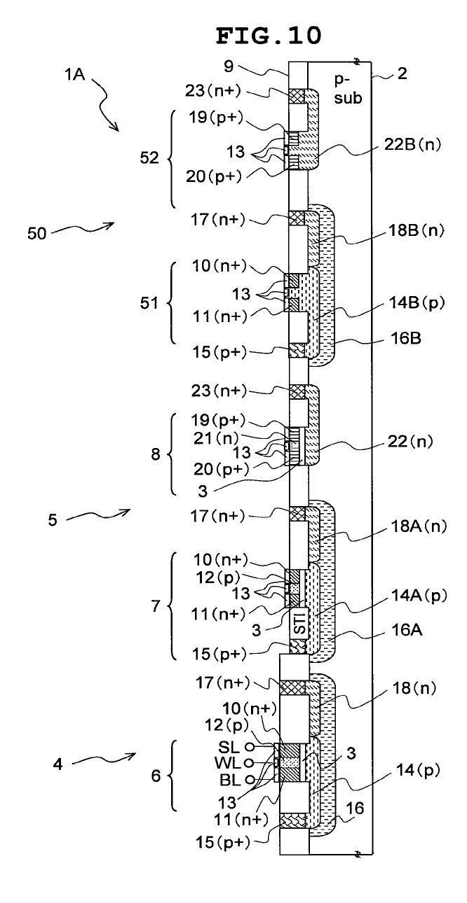

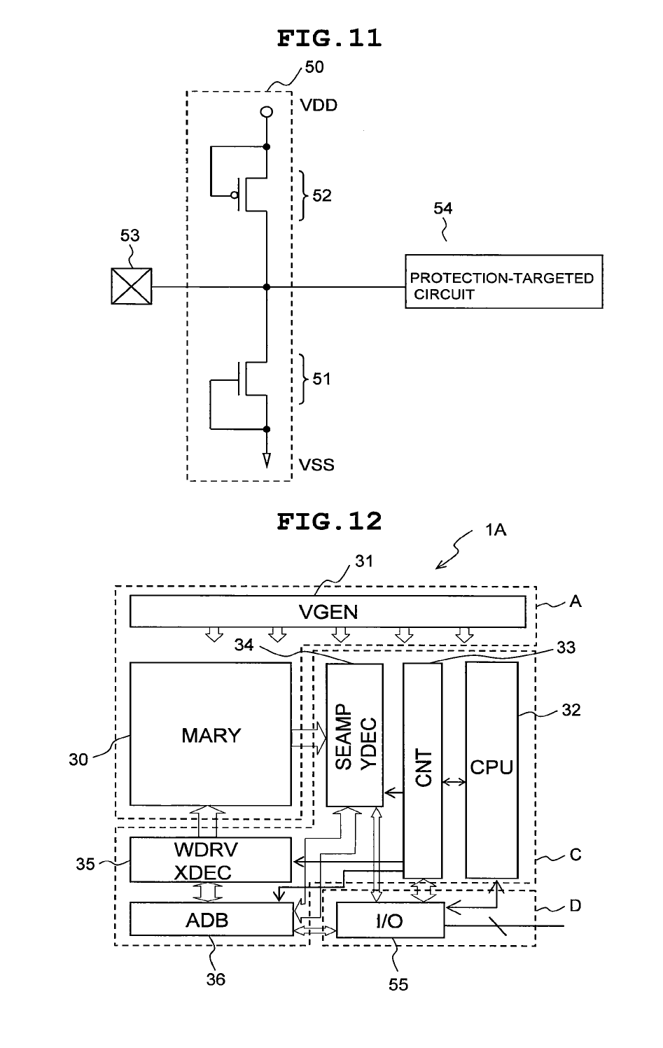

Referring to FIG. 10, the cross sectional structure of a semiconductor integrated circuit according to the second embodiment of the invention is exemplified. In the forms as described below, parts having the same functions as parts of the semiconductor integrated circuit 1 have are identified by the same reference characters, and their descriptions are omitted appropriately. The semiconductor integrated circuit 1A has: a memory 4 including a partially-depleted type (PD) nMOS 6 having the SOI structure; a logic circuit 5 including fully-depleted type (FD) nMOS 7 and pMOS 8 both having the SOI structure; and an input-protection device 50 including an nMOS 51 and a pMOS 52 both having a bulk structure, which are mixedly palletized on a silicon substrate 2. The memory 4 and logic circuit 5 have the same structures as those of the semiconductor integrated circuit 1 as described above, so their descriptions are omitted here. The bulk structure herein refers to a structure that the MOSs are not separated discretely and electrically, e.g. a structure that a plurality of MOS transistors of the same conductivity type are formed in a commonly-used semiconductor region like a well region. The nMOS 51 and pMOS 52 of the bulk structure differ from the fully-depleted type nMOS 7 and pMOS 8 of the SOI structure in that no UTB 3 is arranged, and are not electrically separated from each other. On this account, the nMOS 51 and pMOS 52 having the bulk structure are arranged to be of the same structure as a CMOS, which can form the input-protection device 50 in an I/O circuit for example. Also, the nMOS 51 and pMOS 52 of the bulk structure have backgate regions 14B and 22B respectively, and the backgate regions each adjoin e.g. a channel region uninterruptedly. Between the backgate region 14B and silicon substrate 2, a dn region 16B is disposed, which has the same function as the above-described dn regions 16 and 16A have. Further, between the dn region 16B and STI layer 9, an n region 18B is disposed, which has the same function as the function of the above-described n regions 18 and 18A. FIG. 11 exemplifies a circuit configuration, in which there is an input-protection device including an nMOS and a pMOS, having the bulk structure. Here, the input-protection device 50 is laid out between the external input terminal 53 and an appropriate protection-targeted circuit 54, which is targeted for protection. The input-protection device 50 has an n MOS 51 with a gate connected to a ground terminal VSS and a pMOS 52 with a gate connected to a power-supply terminal VDD. The backgate region 22B of the pMOS 52 is connected to the power-supply terminal VDD. The backgate region 14B of the nMOS 51 is connected to the ground terminal VSS.

As for the input-protection device 50, when a voltage between the ground terminal VSS and power-supply terminal VDD (i.e. normal voltage) is applied to the device through e.g. the external input terminal 53, the nMOS 51 and pMOS 52 are both turned OFF, and the normal voltage will end up being applied to the protection-targeted circuit 54 such as an input buffer. When a positive high-voltage surge higher than the voltage of the power-supply terminal VDD (i.e. excessively-large positive voltage) is applied through the external input terminal 53, the pMOS 52 is turned ON to release the excessively-large positive voltage to the power-supply terminal VDD. Further, as the pMOS 52 has the bulk structure, when the excessively-large positive voltage is applied, a forward current flows through a PN junction between the source and substrate, and therefore the excessively-large positive voltage is released to the silicon substrate 2. In contrast, when a negative high-voltage surge lower than the voltage of the ground terminal VSS (i.e. excessively-large negative voltage) is applied through the external input terminal 53, the nMOS 51 is turned ON to release the excessively-large negative voltage to the ground terminal VSS. Also, a forward current flows between the source and backgate of the nMOS 51, and thus the negative voltage surge can be absorbed. Therefore, the nMOS 51 and pMOS 52, which have the bulk structure, each serve as a protection device, and they can protect the protection-targeted circuit 54 even when an excessively-large positive or negative voltage is applied through the external input terminal 53. In addition, putting the nMOS 51 and pMOS 52 having the bulk structure on the semiconductor integrated circuit 1A allows the design assets including an analog circuit having a bulk structure to be used effectively.

Referring to FIG. 12, a circuit configuration of the semiconductor integrated circuit 1A is exemplified. In the description below, parts having the same functions as parts of the circuit shown in FIG. 2 have are identified by the same reference characters, and their descriptions are omitted appropriately. The semiconductor integrated circuit 1A is partitioned off into a region A, a region C and a region D on the silicon substrate 2. The region C differs from the region B exemplified in FIG. 2 in that it does not include an input-output circuit. In other respects, the region C includes parts as shown in the drawing, which are formed by fully-depleted type MOSs. The region D is a region constituted by an nMOS 51 and a pMOS 52 having the bulk structure, which includes an input-output circuit 55 having e.g. the input-protection device 50 as described above and an appropriate analog circuit. As described above, with the semiconductor integrated circuit 1A, the memory 4, the logic circuit 5, the input-protection device 50 and analog circuit, both constituted by MOSs having the bulk structure, and others are mixedly palletized on one silicon substrate 2. Further, the retention characteristic of the memory 4 can be improved according to the operation mode, and the speed and power consumption of the logic circuit 5 can be made controllable.

### Third Embodiment

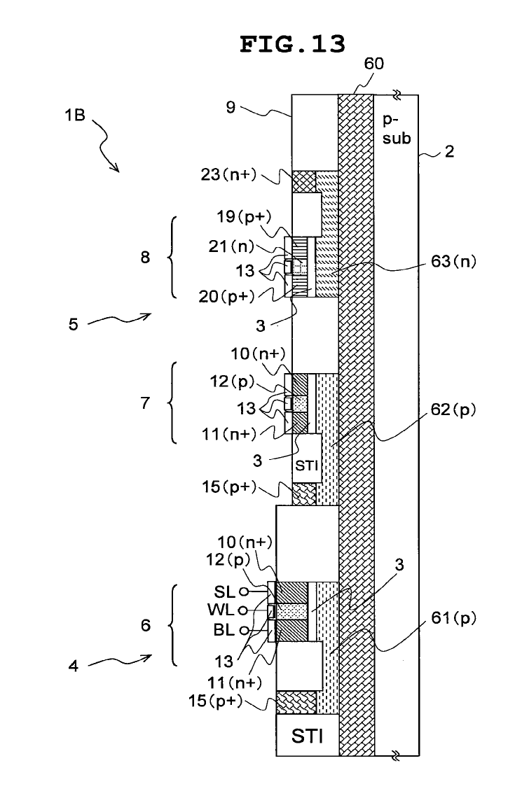

Referring to FIG. 13, the cross sectional structure of a semiconductor integrated circuit according to the third embodiment of the invention is exemplified. The semiconductor integrated circuit 1B differs from the semiconductor integrated circuit 1 as exemplified in FIG. 1 in the structure between the UTB 3 and silicon substrate 2. Specifically, as to the semiconductor integrated circuit 1B, a buried oxide film (hereinafter referred to as TB) 60 is stacked on the silicon substrate 2, which is more resistant to a mechanical or chemical treatment in comparison to the silicon substrate 2. Further, on TB 60, a backgate region 61 of a partially-depleted type nMOS 6, a backgate region 62 of a fully-depleted type nMOS 7, and a backgate region 63 of a fully-depleted type pMOS 8 are stacked respectively. TB 60 isolates the backgate regions 61, 62 and 63 from the silicon substrate 2 electrically. On this account, the semiconductor integrated circuit 1B does not require the dn region 16 and the like for the nMOSs 6 and 7 as exemplified in FIG. 1, which are arranged to prevent the occurrence of leakage current. Therefore, the multilayer structure can be simplified. Moreover, as for the semiconductor integrated circuit 1B, the nMOSs 6 and 7 and pMOS 8 can be laid out more closely because there is not the dn region 16 and the like. This enables the reduction in the size.

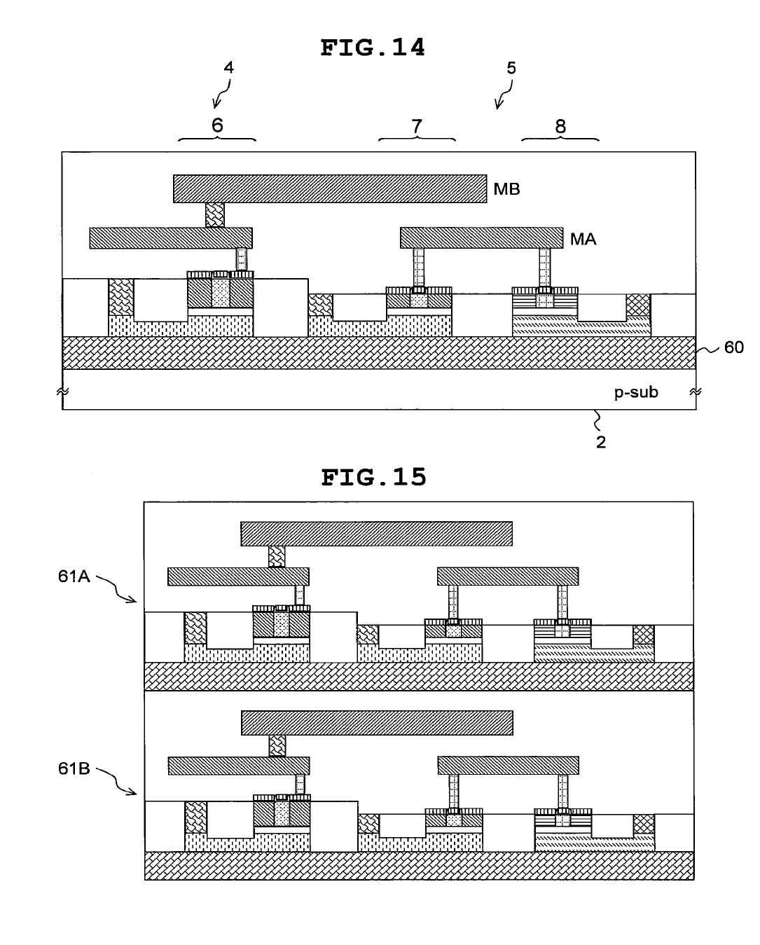

Referring to FIG. 14, an example of the structure of the semiconductor integrated circuit 1B is shown up to an upper-layer conductor line. Specifically, the semiconductor integrated circuit 1B includes a metal line MA and a metal line MB laid out above the metal line MA, which form the upper-layer conductor line. Use of such upper-layer conductor line enables e.g. sending and receiving of signals between the CPU 41 and the memory 42 (see FIG. 8) and between the CPU and the logic circuit 5. In addition, as TB 60 is resistant to a mechanical or chemical treatment in comparison to the silicon substrate 2 as described above, TB can be used as an undermost layer in the multilayer structure instead of the silicon substrate 2 as long as it has a certain extent of thickness. More specifically, the silicon substrate 2 can be removed from the backside of the semiconductor integrated circuit 1B by mechanical or chemical means using TB 60 as a kind of stopper because the silicon substrate 2 is made of typical silicon. In this step, an N silicon layer or the like may be disposed at the interface of TB 60 and the silicon substrate 2 in advance if required.

Referring to FIG. 15, a situation where a semiconductor integrated circuit 61A is stacked on a semiconductor integrated circuit 61B is exemplified. The semiconductor integrated circuits 61A and 61B are each formed by removing the silicon substrate 2 through a mechanical or chemical process thereby to make TB 60 its undermost layer. The semiconductor integrated circuits 61A and 61B are thinner than the semiconductor integrated circuit 1B by a quantity corresponding to the thickness of the silicon substrate 2 removed therefrom. Therefore, even when the integrated circuits are stacked, the thickness of the resultant stack is smaller. As a result, a circuit structure highly integrated in the three dimension can be attained by stacking the semiconductor integrated circuits 61A and 61B. In this process, the structure as described above may be formed by removal of the silicon substrate 2 in wafers and stacking in wafers, followed by dicing the resultant wafer into pieces with required sizes.

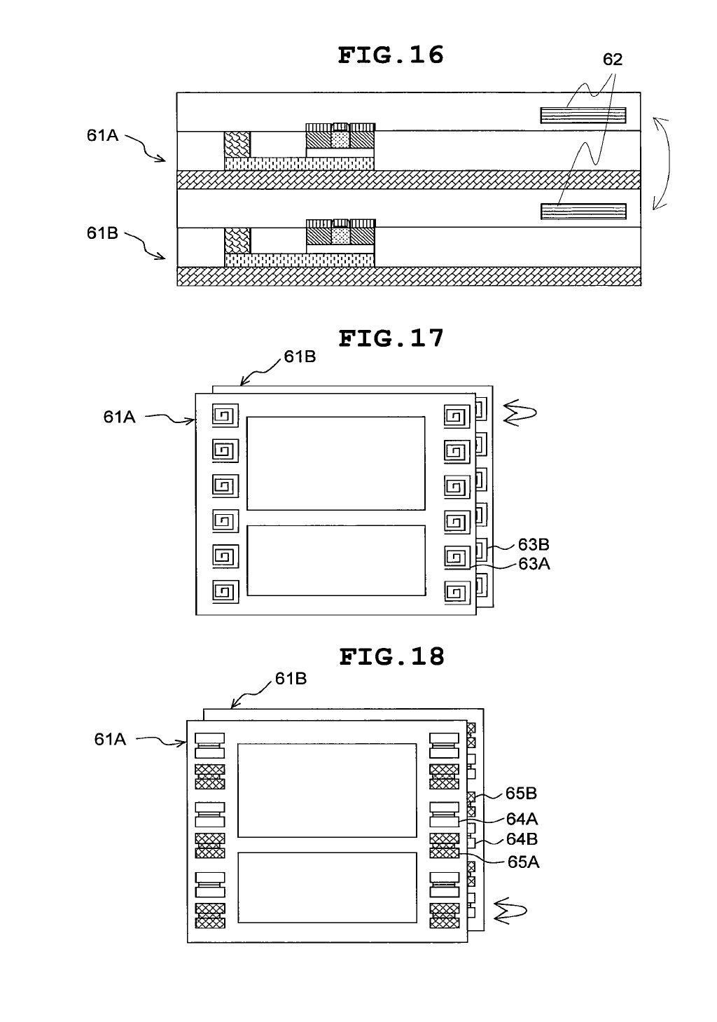

Next, a structure which enables communication between the semiconductor integrated circuits 61A and 61B thus stacked will be described with reference to FIGS. 16 to 18. As to the semiconductor integrated circuits 61A and 61B, when TB 60 is made an undermost layer, not only the connection between the semiconductor integrated circuits 61A and 61B can be made through wiring, but also wireless communication and optical communication can be performed. Specifically, as exemplified by FIG. 16, communication devices 62 are disposed for the semiconductor integrated circuits 61A and 61B respectively. FIG. 17 shows an example where a coil is used as the communication device. In this example, using the respective upper-layer conductor lines, windings 63A and 63B are provided on the semiconductor integrated circuits 61A and 61B. As the semiconductor integrated circuits 61A and 61B each forma thin layer, the distance between the windings 63A and 63B is made smaller. As a result, the windings 63A and 63B can increase the mutual inductance. The current flowing through one of the windings, e.g. the winding 63A generates a magnetic field, which induces current flowing through the other winding, e.g. the winding 63B. Hence, a signal arising in the one winding can be read out in the other winding with ease. Therefore, the semiconductor integrated circuits 61A and 61B are electromagnetically coupled by the windings 63A and 63B, which enables wireless communication between the layers.

Referring to FIG. 18, an example where a light-emitting device and a light-receiving device are used as the communication device is shown. In this example, a photoreceptor 64A as a light-receiving device and a phototransistor 65A as a light-emitting device are provided on the semiconductor integrated circuit 61A, and a photoreceptor 64B and a phototransistor 65B are provided on the semiconductor integrated circuit 61B with the proviso that the phototransistor 65A is opposed to the photoreceptor 64B, and the photoreceptor 64A is opposed to the phototransistor 65B. Here, the semiconductor integrated circuits 61A and 61B each form a thin layer, and therefore the distance between the light-emitting device and the light-receiving device can be made smaller. Further, if the phototransistor and the photoreceptor are arranged alternately, interlayer optical communication can be performed between the semiconductor integrated circuits 61A and 61B even with devices formed from silicon and having a low light emission efficiency and a light receiving efficiency in general. When the semiconductor integrated circuits 61A and 61B corresponding in structure to the semiconductor integrated circuit 1B with the silicon substrate 2 removed are stacked as described above, a circuit structure highly integrated in the three dimension can be attained, and interlayer optical communication and wireless communication can be performed with ease.

While the invention made by the inventor has been described above based on the embodiments specifically, the invention is not so limited. It is needless to say that various changes and modifications may be made without departing from the subject matters hereof.

For instance, while it has been stated that the parts in the region A exemplified by FIG. 2 are constituted by partially-depleted type MOSs, it is sufficient to use only the nMOSs 6. Making this arrangement, the cost in actual design can be reduced. In this case, a fully-depleted type MOS may generate a pulse in the power-supply circuit 31 to input the pulse to the circuits in the region B. Also, if a plurality of MOSs are arranged in stages between the power supply and the ground, and the voltages applied to the plurality of MOSs are restricted, the power-supply circuit can be constituted by only fully-depleted type MOSs. In this case, the region A includes only the memory cell array 30. In addition, it has been stated that the circuits included in the region B are formed by fully-depleted type MOSs. However, of the circuits, the one which feeds an input directly to the memory cell array 30 may be partially included in the region A. Further, a portion of the analog circuit can be formed in the region A. Still further, in the circuits, e.g. correction of the variation in threshold voltage and dynamic control of the threshold voltage according to the operation mode may be performed. The size of the region CN exemplified in FIG. 3 is just an example, and therefore the size with respect to the bit lines may be larger than that shown in the drawing.

While in “0” Write exemplified in FIG. 7 the voltage of the backgate terminal BG is zero volt, it is not so limited. For instance, the voltage of the backgate terminal BG may be set to a negative value to accelerate the impact-ionization. Further, it has been stated that in the circuit configuration of the semiconductor integrated circuit 1A as exemplified in FIG. 12, the region A includes the power-supply circuit 31. However, the power-supply circuit 31 may be arranged in the region C depending on the circuit configuration. Moreover, the semiconductor integrated circuit 1B as exemplified in FIG. 13 may include the nMOS 51 and pMOS 52 having the bulk structure of the semiconductor integrated circuit 1A as exemplified in FIG. 10.

While a two-layer structure in which the semiconductor integrated circuits 61A and 61B are stacked has been shown in FIG. 15, the structure is not so limited, and a multilayer structure constituted by three or more layers may be made. The structures of the semiconductor integrated circuits 61A and 61B are based on that of the semiconductor integrated circuit 1B as exemplified in FIG. 13. However, it is not necessary that all the layers have a common structure. For instance, the layers may include the different circuits. Further, depending on the layers, it is not necessary to include all the regions as described above on the silicon substrate 2.

As communicating means which are enabled by stacking the semiconductor integrated circuits 61A and 61B, wireless communication using coils and optical communication using phototransistors and photoreceptors have been exemplified with reference to FIGS. 17 and 18, the communication means are not so limited. The communicating means may include providing a metal plate on the semiconductor integrated circuit 61A and another metal plate on the semiconductor integrated circuit 61B, which is opposed to the metal plate on the circuit 61A. Making an arrangement like this, the distance between the opposing two metal plates can be made extremely small because the semiconductor integrated circuits 61A and 61B each form a thin layer, and therefore the function of a capacitor formed by the two metal plates, namely capacitance, can be enhanced. As a result, the wireless communication by capacitance coupling between the semiconductor integrated circuits 61A and 61B is facilitated.

1-14. (canceled)

15. A semiconductor integrated circuit including a first MOS transistor formed in a first region of a semiconductor substrate and a second MOS transistor formed in a second region of the semiconductor substrate, comprising:
a first buried oxide layer formed over the first region of the semiconductor substrate;
a first silicon layer formed over the first buried oxide layer;
a first shallow trench isolation formed in the first silicon layer;
a first source region of the first MOS transistor formed in the first silicon layer;
a first drain region of the first MOS transistor formed in the first silicon layer;
a first channel region of the first MOS transistor formed in the first silicon layer and formed between the first source region and the first drain region;
a first gate insulating film of the first MOS transistor formed over the first channel region;
a first gate electrode of the first MOS transistor formed over the first gate insulating film;
a second buried oxide layer formed over the second region of the semiconductor substrate;
a second silicon layer formed over the second buried oxide layer;
a second shallow trench isolation formed in the second silicon layer;
a second source region of the second MOS transistor formed in the second silicon layer;
a second drain region of the second MOS transistor formed in the second silicon layer;
a second channel region of the second MOS transistor formed in the second silicon layer and formed between the second source region and the second drain region;
a second gate insulating film of the second MOS transistor formed over the second channel region; and
a second gate electrode of the second MOS transistor formed over the second gate insulating film,
wherein the first MOS transistor constitutes a memory cell,
wherein the second MOS transistor constitutes a logic circuit,
wherein a thickness of the first silicon layer is larger than a thickness of the second silicon layer, and
wherein a thickness of the first shallow trench isolation is larger than a thickness of the second shallow trench isolation.

16. The semiconductor integrated circuit according to claim 15,
wherein the first MOS transistor: is a partially-depleted type, and
wherein the second MOS transistor is a fully depleted type.

17. The semiconductor integrated circuit according to claim 16,
wherein a back gate region is formed in the semiconductor substrate and under the first buried oxide layer.

18. The semiconductor integrated circuit according to claim 17,
wherein the first MOS transistor is an n-type MOS transistor.

19. The semiconductor integrated circuit according to the claim 18,
wherein the memory cell has a “0” write operation and a “1” write operation,
wherein the memory cell is constructed to perform the “0” write operation by accumulating carriers into an undepleted portion of the first channel region to cause a threshold voltage of the first MOS transistor to become low, and
wherein the memory cell is constructed to perform the “1” write operation by emitting the accumulated carriers into an undepleted portion to cause the threshold voltage of the first MOS transistor to become high.

20. The semiconductor integrated circuit according to claim 19,
wherein the memory cell performs the “0” write operation when the first gate electrode and the first drain region receive a higher voltage than the first source region and the back gate region, and
wherein the memory cell performs the “1” write operation when the first gate electrode receives a higher voltage than the first source region and the back gate region, and the first drain region receives a lower voltage than the first source region and the back gate region.

21. The semiconductor integrated circuit according to claim 20,
wherein the memory cell is a DRAM.

22. The semiconductor integrated circuit according to claim 15,
wherein a thickness of the first buried oxide layer and a thickness of the second buried oxide layer are the same.

23. The semiconductor integrated circuit according to claim 22,
wherein a bottom of the first shallow trench isolation reaches to the first buried oxide layer, and
wherein a bottom of the second shallow trench isolation reaches to the second buried oxide layer.

24. The semiconductor integrated circuit according to claim 15,
wherein silicide layers are formed on the first source region, the first drain region, the first gate electrode, the second source region, the second drain region, and the second gate electrode.
